(19) United States
(12) Patent Application Publication
(10) Pub. No.: US 2020/0111647 A1
(43) Pub. Date: Apr. 9, 2020

(54) Plasma-Treatment Device for Contactlessly Supplying HF Voltage to a Movable Plasma Electrode Unit and Method for Operating Such a Plasma-Treatment Device

(71) Applicant: Meyer Burger (Germany) GmbH, Hohenstein-Ernstthal (DE)

(72) Inventors: Hermann Schlemm, Milda (DE); Mirko Kehr, Amtsberg (DE); Uwe Scheit, Frankfurt (Oder) (DE); Erik Ansorge, Chemnitz (DE); Daniel Decker, Ehrenfriedersdorf (DE)

(21) Appl. No.: 16/303,150

(22) PCT Filed: May 18, 2017
(86) PCT No.: PCT/EP2017/061928

§ 371 Date: Nov. 20, 2018

(30) Foreign Application Priority Data
May 20, 2016 (EP) 16170628.8

(51) Int. Cl. H01J 37/32; H01J 37/248

(52) U.S. Cl. CPC H01J 37/32577; H01J 37/32651; H01J 37/32568; H01J 37/248

(57) ABSTRACT

The invention relates to a plasma-treatment device, in which a plasma electrode unit can be inserted into and removed from a processing chamber, and in which high-frequency power generated by a generator is transmitted to the plasma electrode unit by means of one or more electromagnetic fields and without an electrical ohmic contact. For this purpose, the plasma-treatment device comprises a transmission apparatus, which contains a primary coupling part, which is arranged inside the processing chamber and can generate an electromagnetic field. The plasma electrode unit contains a secondary coupling part, which is rigidly connected to the plasma electrode unit and is suitable for receiving the electromagnetic field and converting it into alternating electrical power. Furthermore, a method for operating such a plasma-treatment device is provided.

### CROSS REFERENCE TO RELATED APPLICATIONS

This application is the U.S. national stage of International Application No. PCT/EP2017/061928, filed on 2017 May 18. The international application claims the priority of EP 16170628.8 filed on 2016 May 20; all applications are incorporated by reference herein in their entirety.

### BACKGROUND

The invention relates to a plasma-treatment device for contactlessly supplying high-frequency voltage to a movable plasma electrode unit, which is suitable for generating a capacitively coupled plasma, in particular in a vacuum. The invention also relates to a method for operating such a plasma-treatment device.

Plasma processes are used in the production of solar cells, in microelectronics or for finishing substrate surfaces (such as glass), for example, in order to deposit or remove layers or particles, to dope layers, for example by means of plasma immersion ion implantation, or to clean or activate the surface of a substrate.

In capacitively coupled plasmas, the substrate to be treated is located in a chamber between two plasma electrodes, high-frequency voltage being supplied to at least one of said plasma electrodes. In this case, a voltage can be applied to the substrate as a result of said substrate being in direct contact with one of the plasma electrodes. This is suitable in particular for plasma-treatment devices in which the substrate(s) is/are arranged in a processing chamber on one of the plasma electrodes such that it/they cannot move. For systems in which the substrates move through a plasma-processing zone, known as in-line systems, it is known to capacitively supply voltage to a substrate; the plasma electrodes themselves, however, being immovable and connected to a voltage supply by means of fixed contacts. Such systems are described in DE 43 01 189 A1 and DE 10 2010 060 762 A1, for example.

In order to increase the throughput of substrates in plasma processing, batch systems in which a plurality of substrates are treated at the same time are used. Here, the surfaces to be processed of the substrates can be arranged next to one another or one on top of the other. In this case, each of the substrates is arranged between the electrodes of a pair of plasma electrodes, which are electrically insulated from one another and are therefore connected to a voltage supply so that a plasma can be capacitively generated between each of said pairs of plasma electrodes. If the substrates are arranged one on top of the other in a plasma electrode unit, up to 200 electrodes, which are arranged in parallel at a typical distance of 3 to 30 mm from one another, are alternately connected to one of at least two voltage supplies, at least one of which is connected to a high-frequency generator of a voltage supply, which is installed outside the plasma-treatment system. One of the at least two voltage supplies can also be earthed.

DE 198 08 206 A1 discloses a plasma-treatment device, in which the plasma electrode unit remains inside the processing chamber, and the plasma electrode unit and the substrate carrier are positioned relative to one another only after the substrate carrier has been introduced into the plasma-treatment chamber such that a substrate is arranged between the electrodes of a pair of plasma electrodes in each case. Voltage can therefore be supplied to the plasma electrode unit by means of an immovably installed, coaxial feedthrough through the wall of the plasma-treatment chamber, for example.

Another batch system, in which the plasma electrode unit is arranged in the substrate carrier (plasma boat) and is inserted into or removed from the processing chamber together with said carrier, is described in DE 10 2008 019 023 A1, for example. As soon as the substrate carrier together with the substrates placed in the plasma electrode unit has been inserted into a plasma-treatment system, an electrical connection is established between the two voltage supplies for the plasma electrode unit and the high-frequency generator.

In the substrate carrier described in DE 10 2008 019 023 A1, the electrical connection is established by means of plug and socket connections, the plugs being inserted from below into the sockets located on the substrate carrier by means of an adjustment device as soon as the substrate carrier is in the intended position in the plasma-treatment system. In order to produce the electrical ohmic contact, typical contact materials are used provided they can be used in the processing environment of the plasma process, in particular even at temperatures between 200 and 500° C. Graphite contact pairs have proven effective, for example.

Contacts of this type and other mechanical contacts, in which a direct mechanical connection and electrical ohmic contact is established between a contact point located on a movable substrate carrier and a contact point installed in the processing chamber, have a typical switching life in the range of 10⁴ switching cycles and therefore have to be serviced or replaced very frequently, for example after just 3 weeks, in the case of short treatment times of the substrate inside the processing chamber. When high-frequency voltages or currents (e.g. 13.56 MHz) are transmitted, the mechanical switching contacts are placed under an even greater amount of stress, thus reducing the service life even more. Furthermore, it is technically more complex to produce mechanical contacts for transmitting high-frequency voltages than for transmitting low-frequency voltages.

### SUMMARY

The invention relates to a plasma-treatment device, in which a plasma electrode unit can be inserted into and removed from a processing chamber, and in which high-frequency power generated by a generator is transmitted to the plasma electrode unit by means of one or more electromagnetic fields and without an electrical ohmic contact. For this purpose, the plasma-treatment device comprises a transmission apparatus, which contains a primary coupling part, which is arranged inside the processing chamber and can generate an electromagnetic field. The plasma electrode unit contains a secondary coupling part, which is rigidly connected to the plasma electrode unit and is suitable for receiving the electromagnetic field and converting it into alternating electrical power. Furthermore, a method for operating such a plasma-treatment device is provided.

### DETAILED DESCRIPTION

Therefore, the object of the invention is to provide a plasma-treatment device, in which a plasma electrode unit can be inserted into and removed from the plasma-treatment device, and in which high-frequency voltage is supplied to the plasma electrode unit such that the disadvantages of the prior art are prevented or reduced.

The object is achieved by a plasma-treatment device according to claim 1 and by a method for operating such a plasma-treatment device according to claim 14. Preferred embodiments can be found in the dependent claims.

The plasma-treatment device according to the invention comprises a processing chamber, a plasma electrode unit and a transmission apparatus. The plasma electrode unit consists of at least one pair of plasma electrodes made up of a first plasma electrode and a second plasma electrode, which are arranged in parallel, are opposite one another and are electrically insulated from one another. In this case, a “plasma electrode unit” is understood to mean any arrangement of plasma electrode pairs, in which all the first plasma electrodes of the pairs of plasma electrodes are connected to one another so as to conduct electricity by means of ohmic contact and all the second plasma electrodes of the pairs of plasma electrodes are connected to one another so as to conduct electricity by means of ohmic contact in each case. The plasma electrode unit is suitable for being inserted into and removed from the processing chamber, the plasma electrode unit preferably being inserted, removed and moved as a whole. The plasma electrode unit can, in this case, be part of a substrate carrier, for example, so that one or more substrates, each of which is arranged between the plasma electrodes of a pair of plasma electrodes, can be treated by means of a plasma that is generated and maintained in the processing chamber between the plasma electrodes of the pair of plasma electrodes. In this case, “treatment” is understood to mean the application or generation of layers to or on a surface of the substrate, the removal of a layer or of particles from a surface of the substrate, the doping of layers or the cleaning or activation of a surface of the substrate. The electrical power required for generating and/or maintaining the plasma is supplied to the plasma electrodes of the plasma electrode unit from a generator, in particular a high-frequency generator, arranged outside the plasma-treatment device by means of the transmission apparatus when the plasma electrode unit is in a treatment position in the processing chamber. In this case, at least a part of the transmission apparatus is arranged in the processing chamber. Some parts of the transmission unit, such as devices for adapting high-frequency power to the conditions prevailing in the plasma-treatment device, for example pressure, temperature and gas composition, which devices are usually referred to as a matchbox, are preferably located outside the processing chamber.

The plasma-treatment device according to the invention is characterised in that the transmission apparatus contains a primary coupling part arranged inside the processing chamber, and the plasma electrode unit contains a secondary coupling part, which is rigidly connected to the plasma electrode unit. In this case, the primary coupling part and the secondary coupling part are each arranged so as to be suitable for transmitting high-frequency power supplied by the generator to the plasma electrode unit, preferably to each plasma electrode of the plasma electrode unit, by means of electromagnetic fields and without an electrical ohmic contact. In other words, the high-frequency power is contactlessly transmitted to the plasma electrode unit by the transmission apparatus, with “contactless” being understood to mean “without direct, electrical ohmic contact”.

Therefore, the at least one ohmic contact point between the transmission apparatus and the plasma electrode unit required in the prior art is omitted, thus largely avoiding wear of the contact as a result of mechanical abrasion or the formation of arcs, etc. As a result of the contactless transmission, according to the invention, of high-frequency power by means of electromagnetic fields, the possible physical distance between the primary coupling part and the secondary coupling part can lead to virtually wear-free power transmission, thus increasing the service life of the plasma-treatment device and therefore reducing servicing costs.

Transmitting power contactlessly as per the invention is advantageous in particular when transmitting high-frequency powers in the range from 10 kHz to 100 MHz, preferably for frequencies above 1 MHz. Such high-frequency powers can only be poorly transmitted by ohmic contacts. As a result, plasma processes that require a high excitation frequency for generating and maintaining the plasma, such as the deposition of amorphous silicon, can also be carried out in the plasma-treatment device according to the invention.

The primary coupling part and the secondary coupling part contain inductive or capacitive elements for generating an electromagnetic field or for converting said field into alternating electrical power. These inductive and capacitive elements can be integrated in the matchbox of the transmission apparatus or in the electric circuit of the plasma electrode unit, respectively, such that the active power only drops to a minimal extent at said elements, and maximum active power is therefore available for generating and maintaining a plasma between the plasma electrodes of a pair of plasma electrodes of the plasma electrode unit.

The plasma electrodes of the plasma electrode unit are preferably designed so as to be arranged in the plasma-treatment device in a manner insulated against earth potential when the plasma electrode unit is in a treatment position. Furthermore, the primary coupling part and the secondary coupling part are formed so as to be suitable for symmetrically supplying the high-frequency power to plasma electrodes of the plasma electrode unit that are assigned to one another, i.e. to the plasma electrodes of a specific pair of plasma electrodes, with respect to earth potential. Therefore, high-frequency voltages offset by 180° are fed into the different plasma electrodes of the specific pair of plasma electrodes. As a result, the high-frequency voltage applied between the plasma electrodes is twice as high as that fed in in each case, so that the size of the high-frequency voltage fed in in each case can be reduced, in particular approximately halved, with respect to the voltage required for generating and maintaining the plasma. Therefore, only high-frequency voltages that are measured with respect to earth and are comparatively low are applied to the elements of the primary and of the secondary coupling part, to the individual plasma electrodes and to the supply lines between the secondary coupling part and the plasma electrodes, as a result of which parasitic plasmas are largely suppressed, even without the arrangement of insulating or conductive shields. Therefore, the structure of the plasma electrode unit and of the transmission apparatus or the entire plasma-treatment device can be simplified, thus saving costs.

When using inductive elements in the primary and secondary coupling part, high-frequency generators and elements connected to said generators that are suitable for generating an asymmetrical high-frequency voltage can also be used, since the inductive elements generate symmetrical voltages in the secondary coupling part from an asymmetrical voltage provided at the primary coupling part. This has advantages over the use of generators and elements connected thereto, which would be required for generating a symmetrical high-frequency voltage, with regards to costs.

The plasma-treatment device preferably also comprises an adjustment unit, which is suitable for moving the primary coupling part towards or away from the secondary coupling part when the plasma electrode unit is in a treatment position in the plasma-treatment device. The distance between the primary coupling part and the secondary coupling part can therefore be adjusted in each case such that a large distance is set so that the plasma electrode unit can move without damaging the coupling parts during the movement of the plasma electrode unit, whereas the distance in the treatment position is reduced in accordance with the conditions required for transmitting the high-frequency power. When using inductive elements in the coupling parts, i.e. a primary inductor in the primary coupling part and a secondary inductor in the secondary coupling part, the distance in the treatment position is between 3% and 10% of the diameter of the inductors in flat inductors, and between 50% and 100% of the diameter of the inductors in toroidal inductors or cylindrical inductors. When using capacitive elements in the coupling parts, in the treatment position, a distance of 0 (zero) can be set between the primary and the secondary coupling part, or a larger distance in the range from 0.1 to 10 mm can be set. In this case, the adjustment unit can move the primary coupling part by between 5 and 20 mm, for example, preferably by more than 10 mm. In this case, the adjustment unit can be provided with known means, for example with mechanical, pneumatic, hydraulic or electromagnetic drive elements.

In a first embodiment, the primary coupling part comprises at least one primary inductor and the secondary coupling part comprises at least one secondary inductor, each secondary inductor being assigned to a primary inductor. In each case, one end of the secondary inductor is connected to a first plasma electrode of a pair of plasma electrodes so as to conduct electricity, while the other end of the secondary inductor is connected to a second plasma electrode of said pair of plasma electrodes so as to conduct electricity. The at least one primary inductor is suitable for generating an electromagnetic field by means of the high-frequency power supplied by the high-frequency generator, while the at least one secondary inductor is suitable for absorbing the electromagnetic field generated by the at least one primary inductor and generating a high-frequency power which corresponds to the alternating power provided at the primary inductor. The inductors have between 1 and 50 turns, preferably between 3 and 20 turns in this case, the optimum number of turns that can be used reducing with the frequency for high-frequency-related reasons. Typical inductive coupling parts are therefore suitable in particular for transmitting high-frequency powers having a frequency of below 20 MHz, in particular below 10 MHz.

At least one of the at least one primary inductor and at least one of the at least one secondary inductor assigned to said primary inductor are preferably formed as flat inductors. Flat inductors are inductors in which a conductor is formed as a spiral or a meander, with all conductor portions (turns) being located in one plane. The planes of the primary inductor and of the at least one secondary inductor are parallel to one another, the central point of the primary inductor and of the at least one secondary inductor lying on one axis. The design of the primary inductor and of the at least one secondary inductor can either be the same or different. The diameter of the inductors or the lateral dimension (edge length) thereof for a square design is typically in the range from 50 to 250 mm. The inductors can be made of a tubular material or a flat material. For example, a copper tube having a diameter in the range from 4 to 12 mm and a material thickness of 1 to 2 mm, which preferably comprises a silver layer on the surface, can be used as the tubular material, in particular for the primary inductor. A strip material having a thickness of 0.25 to 2 mm and a width of 5 to 50 mm made of copper or aluminium, which advantageously also comprises a silver layer on the surface, can be used as the flat material, in particular for the primary inductor, for example.

Alternatively, at least one of the at least one primary inductor and at least one of the at least one secondary inductor assigned to said primary inductor are formed as cylindrical inductors, in which the turns of the inductor lie one on top of the other and not on one plane. Cylindrical inductors are typically made of tubular material, as already described with reference to the flat inductors. The inductors preferably have a diameter in the range from 30 to 200 mm, the primary inductor and the at least one secondary inductor advantageously having the same diameter. The primary inductor and the at least one secondary inductor can either have the same number of turns or a different number of turns. The primary inductor and the at least one secondary inductor have the same central axis in this case.

In both embodiments, the primary inductor can be cooled using simple means, for example by means of cooling the inside of the inductor with a fluid, e.g. water, when using a tubular material. This is required in particular when transmitting high-frequency powers of more than 1 kW. In contrast, the secondary inductor can only be cooled with difficulty, and therefore the at least one secondary inductor consists of a temperature-stable material suitable for high frequencies. For temperature ranges of up to 250° C., silver-plated copper or stainless steel inductors can be used, whereas inductors made of highly conductive and polished thin graphite, preferably also having a silver coating, are used for temperatures of up to 500° C. At high frequencies, the high-frequency current predominantly flows on the surface of the inductor material (skin effect), and therefore even inductors made of an insulating material that have a thin, electrically conductive surface coating, for example of graphite, silver, aluminium or copper, can be used.

In a second embodiment, the primary coupling part comprises at least two primary electrodes and the secondary coupling part comprises at least two secondary electrodes, each secondary electrode being assigned to a specific primary electrode and being suitable for forming a capacitor together therewith. The primary electrode of a first capacitor is connected to one connection (terminal) of the high-frequency generator so as to conduct electricity, while the primary electrode of a second capacitor is connected to the other connection (terminal) of the high-frequency generator so as to conduct electricity. The secondary electrode of the first capacitor is connected to a first plasma electrode of a specific pair of plasma electrodes so as to conduct electricity, while the secondary electrode of the second capacitor is connected to a second plasma electrode of the specific pair or plasma electrodes so as to conduct electricity. A plurality of secondary electrodes that differ in terms of the surface area or the material of the dielectric, for example, can also be assigned to one primary electrode. Therefore, the plurality of secondary electrodes can absorb different electrical powers and supply them to different regions of the plasma electrode unit in each case.

The primary electrodes of the primary coupling part and the secondary electrodes of the secondary coupling part therefore form at least two separable capacitors, which are suitable for supplying the plasma electrodes of the plasma electrode unit with a symmetrical high-frequency voltage. Typical capacitances of the coupling capacitors are in the range between 0.5 and 2 nF. Since considerably less voltage is intended to drop at the coupling capacitors than the maintaining voltage of the plasma, the coupling capacitors each have a capacitance that is greater than or equal to a minimum capacitance that depends on the requirements of the plasma-treatment device. Therefore, the minimum capacitance for an alternating power having a frequency of 13.56 MHz is 1 nF, for example. Since the voltage drop at the capacitors decreases as the frequency increases, capacitive coupling parts are suitable in particular for transmitting high-frequency powers having a frequency in the range from 10 to 100 MHz, in particular for frequencies of more than 20 MHz.

Any dielectric can be provided between the primary electrode and the secondary electrode of a coupling capacitor, for example the atmosphere prevailing in the processing chamber. In this case, the primary electrode and the secondary electrode are spaced apart from one another during transmission of the alternating power. However, at least one of the primary electrode or the secondary electrode of a specific capacitor preferably comprises an additional dielectric. This means: an additional dielectric is arranged on the primary electrode or on the secondary electrode or on the primary electrode and the secondary electrode. The dielectric is preferably between 0.25 and 1 mm thick and consists of a material having a relative permittivity of more than 5. This can be aluminium oxide having a relative permittivity of 8 to 9, for example. The primary coupling part is preferably moved towards the secondary coupling part by means of the adjustment unit when the plasma electrode unit is in a treatment position in the processing chamber such that the dielectric is then in mechanical contact with the respectively assigned secondary electrode or primary electrode of the specific capacitor. Once the plasma-treatment process has finished, the primary coupling part is re-removed from the secondary coupling part, and the coupling capacitors are therefore separated such that the plasma electrode unit can be re-removed from the plasma-treatment device.

The primary electrode and the secondary electrode of at least one specific capacitor particularly preferably each have a non-planar surface, which is opposite the other electrode in each case and corresponds to the shape of the non-planar surface of the other electrode in each case. In this case, the surfaces are intended to be shaped such that the primary electrode and the secondary electrode engage in one another without the formation of a parasitic gap when the primary electrode and the secondary electrode are brought into contact with one another. Furthermore, the shape of said surface has to be suitable for the primary electrode and the secondary electrode to be released from one another again, both easily and without damaging the electrodes. The shape of the surfaces is advantageously selected such that the primary electrode and the secondary electrode align themselves relative to one another when the primary electrode and the secondary electrode are brought into contact with one another.

The embodiments described thus far of the primary and of the secondary coupling part are particularly suitable for transmitting high-frequency power to a plasma electrode unit, which is arranged in the processing chamber such that it is stationary and cannot move whilst power is transmitted. For this purpose, the primary coupling part or the secondary coupling part preferably comprises an alignment device, by means of which the inductive or capacitive elements of the primary coupling part and of the secondary coupling part can be positioned relative to one another in the treatment position in a direction that is perpendicular to the distance between the primary coupling part and the secondary coupling part so as to ensure that a desired, predetermined amount of high-frequency power is transmitted.

In another embodiment of the capacitive transmission of power, the primary electrode and the secondary electrode of at least one specific capacitor each comprise at least two plate-shaped regions, which each extend from a common connecting region towards the other electrode in each case, and extend in a direction in which the plasma electrode unit is inserted into and removed from the plasma-treatment device. The number of plate-shaped regions of the primary electrode and of the secondary electrode of a specific capacitor can be the same or can differ by one. The primary electrode and the secondary electrode are each formed as a comb, the plate-shape regions forming the teeth of the particular electrode comb and reaching into the gaps between the teeth of the other electrode comb. In this case, the plate-shaped regions of the primary electrode and of the secondary electrode are opposite one another, at least in part, when the plasma electrode unit is in a treatment position in the plasma-treatment device. This means that the plate-shaped regions of the primary electrode and of the secondary electrode are opposite one another in a direction extending perpendicularly to the plane of extension of the plate-shaped regions. In this direction, the plate-shaped regions are spaced apart by between 0.1 and 10 mm, the atmosphere prevailing in the processing chamber being located between the regions. The distance is intended to be the perfect balance between a large coupling capacitance, associated with a small distance, and the prevention of a parasitic plasma between the electrodes, which is associated with a large distance. By means of this design of the primary and secondary electrodes, it is possible to particularly expediently implement capacitive coupling in order to transmit the high-frequency power without using an adjustment unit and without having to position the secondary coupling part of the plasma electrode unit with respect to the primary coupling part of the transmission apparatus with a high degree of accuracy. In a particular embodiment, the plasma electrode unit can even move during transmission of the high-frequency power, and therefore the transmission of power is also suitable for plasma-treatment devices in which the plasma electrode unit is continuously moved, known as continuous systems. In a particularly preferred embodiment, the plasma electrode unit moves linearly into a direction along which the plasma electrode unit is moved into the plasma-treatment device and moved out of it,

In all the embodiments, the inductive or capacitive elements in both the primary coupling part and in the secondary coupling part, i.e. the inductors or capacitor electrodes, can be shielded by means of insulating or conductive elements in order to prevent the formation of parasitic plasmas.

According to a particular embodiment, the plasma-treatment device contains a plurality of plasma electrode units and a plurality of transmission apparatuses. In this case, each plasma electrode unit is assigned to a specific transmission apparatus and each transmission apparatus comprises a primary coupling part and each plasma electrode unit comprises a secondary coupling part, which are suitable for transmitting high-frequency electrical power to the particular plasma electrode unit by means of electromagnetic fields and without being in electrical ohmic contact with one another. In other words: the primary and secondary coupling parts are formed as described above.

The method according to the invention for operating the plasma-treatment device according to the invention comprises the steps of inserting the plasma electrode unit into the processing chamber, generating an electromagnetic field in the primary coupling part and transmitting the high-frequency electrical power to the secondary coupling part, disconnecting the primary coupling part from the high-frequency electrical power supplied by the high-frequency generator, and removing the plasma electrode unit from the processing chamber. The method begins with inserting the plasma electrode unit into the processing chamber along a first direction until the plasma electrode unit is in a treatment position in the processing chamber and the primary coupling part and the secondary coupling part are opposite one another, at least in part. Once the plasma electrode unit has been inserted, an electromagnetic field is generated in the primary coupling part by applying a high-frequency electrical power supplied by a generator to the primary coupling part. Said electromagnetic field transmits the high-frequency electrical power to the secondary coupling part, thus generating and maintaining a plasma between the plasma electrodes of a pair of plasma electrodes of the plasma electrode unit. Once an operating aim has been reached in the processing chamber, the primary coupling part is disconnected from the high-frequency electrical power supplied by the generator and the plasma electrode unit is then removed from the processing chamber along the first direction. The method according to the invention is advantageous on account of the contactless and therefore low-wear transmission of high-frequency power from a generator to a plasma electrode unit. The plasma-treatment device can therefore be operated for a longer amount of time than a plasma-treatment device having ohmic contacts before needing to be serviced.

When the plasma electrode unit is inserted, it is preferably moved such that, once it reaches the treatment position, a first distance is provided between the primary coupling part and the secondary coupling part. Following this insertion and before generating the electromagnetic field, the primary coupling part is moved towards the secondary coupling part by means of an adjustment unit until a second distance is formed between the primary coupling part and the secondary coupling part. In this case, the second distance is smaller than the first distance. After the primary coupling part has been disconnected from the alternating electrical power and before removing the plasma electrode unit from the processing chamber, the primary coupling part is moved away from the secondary coupling part by means of the adjustment unit until a third distance is formed between the primary coupling part and the secondary coupling part. In this case, the third distance is larger than the second distance and can preferably be equal to the first distance. The distance between the primary and the secondary coupling part is therefore set by the adjustment unit such that, during the steps of inserting and removing the plasma electrode unit into or from the processing chamber, a large distance is provided that prevents the coupling parts from getting damaged, and, during the step in which the alternating power is transmitted, a smaller distance is provided, which is optimal for transmitting the alternating power.

If the primary coupling part comprises at least one primary inductor and if the secondary coupling part comprises at least one secondary inductor, it is advantageous to cool the primary inductor during the step of generating an electromagnetic field and transmitting the high-frequency power.

### BRIEF DESCRIPTION OF THE DRAWINGS

The invention will be described in the following in more detail with reference to the drawings, in which:

FIG. 1 is a schematic view of the plasma-treatment device according to the invention, comprising a plasma electrode unit and a transmission apparatus,

FIG. 2 is a schematic view of the plasma-treatment device according to the invention, comprising a plurality of plasma electrode units and a plurality of transmission apparatus,

FIG. 3 is a schematic view of a first embodiment of the plasma-treatment device according to the invention, comprising inductive elements in the coupling parts,

FIG. 4A is a schematic cross section through a primary and a secondary coupling part, both of which contain flat inductors,

FIG. 4B is a plan view of the flat inductors in FIG. 4A,

FIG. 4C is a schematic perspective view of the two flat inductors in FIG. 4A,

FIG. 5 is a schematic cross section through a primary and a secondary coupling part, both of which contain cylindrical inductors,

FIG. 6 is a schematic view of a second embodiment of the plasma-treatment device according to the invention, comprising capacitive elements in the coupling parts,

FIG. 7 is a schematic cross section through a primary and a secondary coupling part, in which the electrodes of the coupling capacitors are planar,

FIG. 8 is a schematic cross section through a primary and a secondary coupling part, in which the electrodes of the coupling capacitors are non-planar, and

FIG. 9 is a schematic cross section through a primary and a secondary coupling part, in which the electrodes of the coupling capacitors are formed as comb electrodes.

### DETAILED DESCRIPTION OF THE PREFERRED EMBODIMENTS

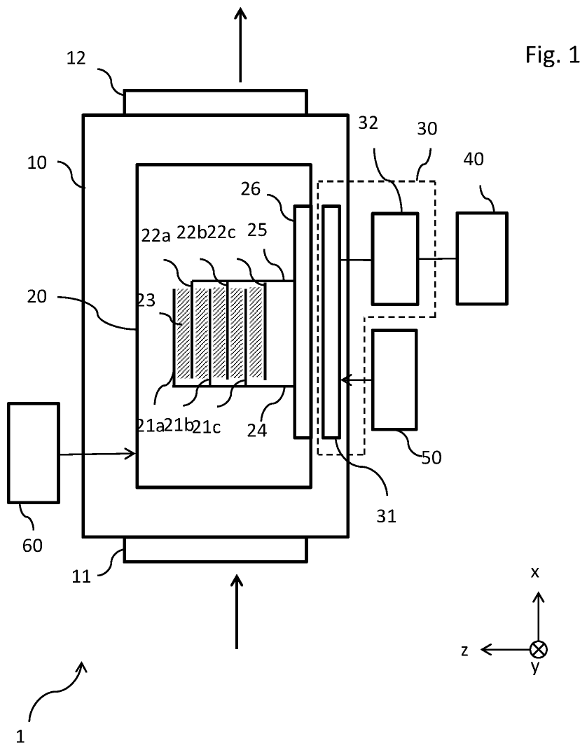

FIG. 1 is a schematic view of a plasma-treatment device 1 according to the invention, comprising the elements essential to the invention. The plasma-treatment device 1 contains a processing chamber 10, into which a plasma electrode unit 20 can be inserted via a lock 11 and from which said unit can be removed again via a lock 12 (shown by the arrows in the x direction). The plasma-treatment device 1 can, however, also contain just one lock 11 or 12, by means of which the plasma electrode unit 20 can be inserted into and removed from the processing chamber. Furthermore, a lock can also be arranged at another point in the processing chamber, for example at its upper end with respect to the z direction in the drawing.

The plasma electrode unit 20 can preferably only move in the processing chamber 10 in the direction in which it is inserted and removed, but can also move in other directions in the xyz coordinate system or can be rotated about an axis if the corresponding devices for carrying out the movement are provided. In the case shown, the plasma electrode unit 20 comprises five pairs of plasma electrodes, which are formed of three first plasma electrodes 21a to 21c and three second plasma electrodes 22a to 22c. The first plasma electrode 21a and the second plasma electrode 22a thus form a first pair of plasma electrodes, for example, while the second plasma electrode 22a and the first plasma electrode 21b form a second pair of plasma electrodes. All the first plasma electrodes 21a to 21c are connected to one another via a supply line 24 so as to conduct electricity and are supplied with a first electrical voltage. All the second plasma electrodes 22a to 22c are connected to one another via a supply line 25 so as to conduct electricity and are supplied with a second electrical voltage. When the corresponding voltages are applied, a plasma 23 forms between the first plasma electrode and the second plasma electrode of a pair of plasma electrodes, wherein substrates which are arranged between the electrodes (not shown in this case) can be treated by means of the plasma, for example. The plasma electrode unit 20 can comprise any number of pairs of plasma electrodes that is equal to or greater than 1, it also being possible for individual plasma electrodes of specific pairs of plasma electrodes to be supplied with voltages other than the first or the second voltage. The plasma electrodes of the plasma electrode unit 20 can also be arranged vertically, i.e. in the z direction.

The plasma-treatment device 1 further comprises a transmission apparatus 30, which can transmit high-frequency power, which is supplied by a generator 40, to the plasma electrode unit 20 without direct ohmic contact. For this purpose, the transmission apparatus 30 contains a primary coupling part 31, which is arranged inside the processing chamber 10 and can generate an electromagnetic field, by means of which the high-frequency power is transmitted to a secondary coupling part 26 that is part of the plasma electrode unit 20. The secondary coupling part 26 then provides corresponding electrical voltages and electrical powers to the individual plasma electrodes of the pair of plasma electrodes. The transmission apparatus 30 further contains a matchbox 32, by means of which high-frequency power supplied by the generator 40 can be adapted to the conditions inside the processing chamber 10.

In order to be able to adjust the distance between the primary coupling part 31 and the secondary coupling part 26 in accordance with the particular work step, the plasma-treatment device 1 comprises an adjustment unit 50, which is used to move the primary coupling part 31 towards or away from the secondary coupling part 26. In the case shown, this corresponds to a movement of the primary coupling part 31 along the z direction. However, the primary coupling part 31 can alternatively also be moved along the y direction if the primary coupling part 31 and the secondary coupling part 26 are opposite one another in the y direction. In other words: the arrangement shown in FIG. 1 of the primary coupling part 31 and of the secondary coupling part 26 in the xyz coordinate system is not mandatory, instead this depends on the direction of movement of the plasma electrode unit 20 in the processing chamber 10 and on additional spatial requirements of the plasma-treatment device 1. This means: the secondary coupling part 26 can be arranged on a lower end of the plasma electrode unit 20 (with respect to the z direction), as shown in FIG. 1, or on an upper end of the plasma electrode unit 20 with respect to the z direction, on a front end of the plasma electrode unit 20 with respect to the y direction or on a rear end of the plasma electrode unit 20 with respect to the y direction, or even on an end of the plasma electrode unit 20 with respect to the x direction if this does not clash with the insertion and removal of the plasma electrode unit 20 into or from the processing chamber 10. Accordingly, the adjustment unit 50 can displace the primary coupling part 31 along the z direction, the y direction or the x direction in order to change the distance between the primary coupling part 31 and the secondary coupling part 26. If the coupling parts 31 and 26 of the transmission apparatus 30 contain inductive elements for transmitting the high-frequency power, as is described hereinafter with reference to the first embodiment, the adjustment unit 50 can also be omitted, since the plasma electrode unit 20 only has to be moved over the primary coupling part 31, for example in the x direction, and any additional movement of the primary coupling part, for example in the z direction, is not necessary.

In order to accurately position the primary coupling part 31 and the secondary coupling part 26 in the x-y plane relative to one another, the plasma-treatment device 1 can further comprise an alignment device 60, which can displace the primary coupling part 31 and/or the plasma electrode unit 20 and the secondary coupling part 26 rigidly connected thereto in the x and/or y direction. FIG. 1 shows the adjustment device 60 acting on the plasma electrode unit 20. If the primary coupling part 31 is intended to be moved in the x and/or y direction, the alignment device 60 can also be formed as a common device together with the adjustment unit 50 or can at least make use of parts of the adjustment unit 50. Particularly advantageous embodiments of the plasma-treatment device 1 comprise only either the adjustment unit 50 or the alignment device 60, or do not comprise either of them.

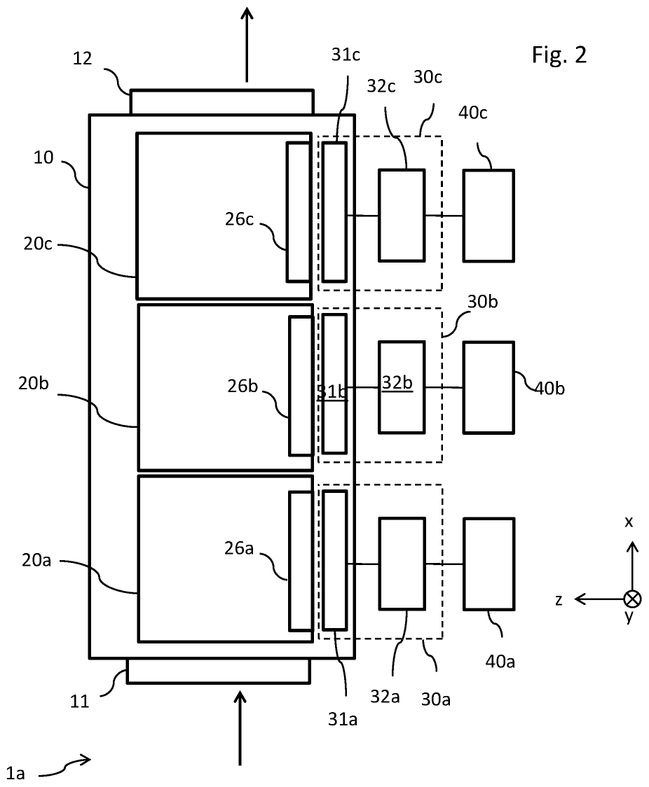

FIG. 2 is a schematic view of a plasma-treatment device 1a, which comprises a plurality of plasma electrode units 20a to 20c and a plurality of transmission apparatuses 30a to 30c. In this case, each transmission apparatus 30a to 30c contains a primary coupling part 31a to 31c. Furthermore, each transmission apparatus 30a to 30c can have its own matchbox 32a to 32c or can also share said matchbox with other transmission apparatuses 30a to 30c. FIG. 2 shows each transmission apparatus 30a to 30c connected to a separate generator 40a to 40c. In this case, too, the high-frequency power from one generator can be distributed among a plurality of transmission apparatuses 30a to 30c. Each plasma electrode unit 20a to 20c contains a secondary coupling part 26a to 26c and has an otherwise similar structure to the plasma electrode unit 20 described in FIG. 1. In this case, different plasma electrode units 20a to 20c can have the same or different designs, for example in terms of the number or arrangement of plasma electrodes in the particular plasma electrode unit. For the sake of clarity, the plasma electrodes, the supply lines, the adjustment units and the alignment devices have not been shown in the drawing. In the embodiment shown in FIG. 2, all the plasma electrode units 20a to 20c are arranged next to one another along the x direction in the plasma-treatment device 1a. However, the plasma electrode units 20a to 20c can also be arranged next to one another along the y direction or one above the other along the z direction, the primary coupling parts 31a to 31c and the transmission apparatuses 30a to 30c then optionally also being arranged in different ways. Furthermore, different plasma electrode units 20a to 20c can also be arranged differently inside the plasma-treatment device 1a.

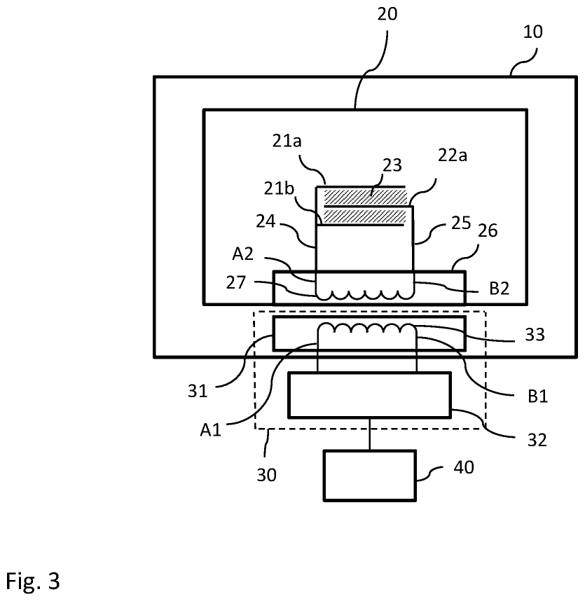

FIG. 3 is a schematic view of a first embodiment of the plasma-treatment device according to the invention, in which the coupling parts contain inductive elements for transmitting the high-frequency power. In order to make the drawing clearer, only components of the plasma-treatment device that are essential for explaining how it works have been shown. The plasma electrode unit 20 and the primary coupling part 31 of the transmission apparatus 30 are arranged in the processing chamber 10. For the sake of depicting said device schematically, only three plasma electrodes 21a, 21b and 22a are shown, which form two pairs of plasma electrodes, between each of which a plasma 23 is generated. The primary coupling part 31 comprises a primary inductor 33, the two connections (terminals) A1 and B1 of which are connected to the matchbox 32. The secondary coupling part 26 contains a secondary inductor 27, one connection (terminal) A2 of which is connected to the first plasma electrodes 21a, 21b via the supply line 24, and the other connection B2 of which is connected to the second plasma electrode 22a via the supply line 25. The primary inductor 33 generates an electromagnetic field by means of the high-frequency power supplied by the generator 40, by means of which field a high-frequency voltage is generated in the secondary inductor 27. A symmetrical high-frequency voltage is formed, in which alternating voltages phase-shifted by 180° are applied to the two connections A2 and B2 in each case. If one of the two connections A2 or B2 is arranged in the centre of the secondary inductor 27, i.e. if the secondary inductor 27 comprises a centre tap, the two high-frequency voltages picked off at the connections A2 and B2 are symmetrical with respect to earth.

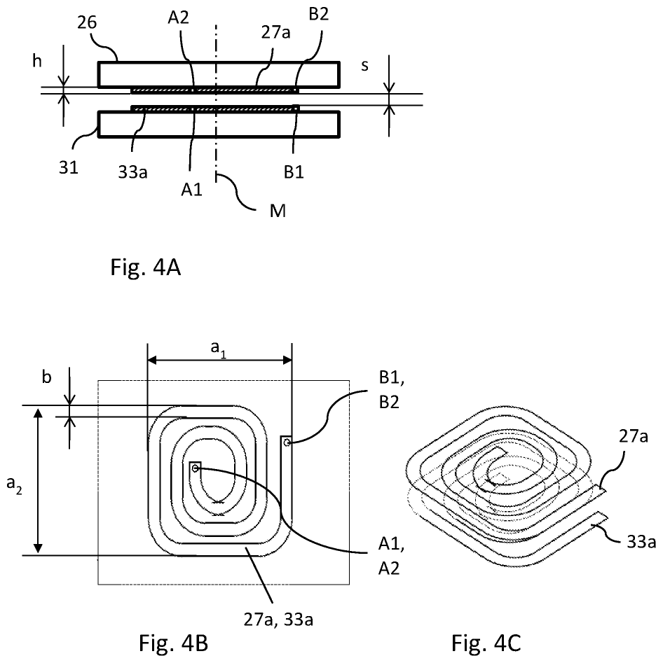

FIG. 4A shows a schematic cross section through a primary and a secondary coupling part 31, 26 of the first embodiment, the primary inductor and the secondary inductor being formed as flat inductors 33a and 27a. In flat inductors, the two connections of the inductor, i.e. the connections A1 and B1 or A2 and B2, lie in one plane with the turns of the inductor in each case. As shown in FIG. 4A, the flat inductors 33a and 27a can be arranged on a surface of the primary coupling part 31 or of the secondary coupling part 26, respectively, or in the surface (i.e. flush with the surface) or inside the particular coupling part. In this case, the flat inductors 33a and 27a are at a distance s from one another, which advantageously remains the same over the entire extension of the flat inductors 33a and 27a. The central points of the two flat inductors 33a and 27a lie on one axis, exactly perpendicularly one above the other, the axis being shown in FIG. 4A by the line M. Each flat inductor 33a, 27a has a height h, which is measured perpendicularly to the plane in which the flat inductor 33a, 27a is arranged in each case. FIG. 4A only shows the height h of the secondary flat inductor 27a for the sake of clarity. The heights of the two flat inductors 33a and 27a can be the same or different.

FIG. 4B is a schematic plan view of the two flat inductors 33a and 27a in FIG. 4A. Both flat inductors 27a and 33a have a helical turn, in which one connection, connection A1 or A2 in FIG. 4B, is arranged in the centre or near to the central point of the inductor, while the other connection, B1 or B2, is arranged on the outer edge of the inductor. However, in rectangular or square flat inductors, the turns can also be arranged in the shape of a meander. In FIG. 4B, both flat inductors 33a and 27a have the same design and the same dimensions when seen in a plan view, which can also be seen in FIG. 4C, which is a perspective view of the flat inductors 33a and 27a. However, the two flat inductors 33a and 27a can also have different designs and dimensions. The dimensions shown in FIG. 4B are the edge lengths a₁ and a₂ of the inductors and the width b of the inductor material. In rectangular flat inductors, both lateral dimensions (edge lengths a₁ and a₂) determine the inductance of the inductor.

A number of examples of materials and dimensions of the flat inductors 33a and 27a and the distance s are given in the following. For example, a flat inductor can be made from tubular material having an external tube diameter of 4 to 12 mm, in which the height h and the width b correspond to the external tube diameter. If the flat inductor is formed from a flat material, the height h is between 0.52 and 2 mm and the width b is between 5 and 20 mm. The diameter or the edge lengths a₁ and a₂ are typically between 50 and 250 mm and the distance s is between 3% and 10% of the diameter or the longer of the two edge lengths, i.e. lies between 1.5 and 25 mm.

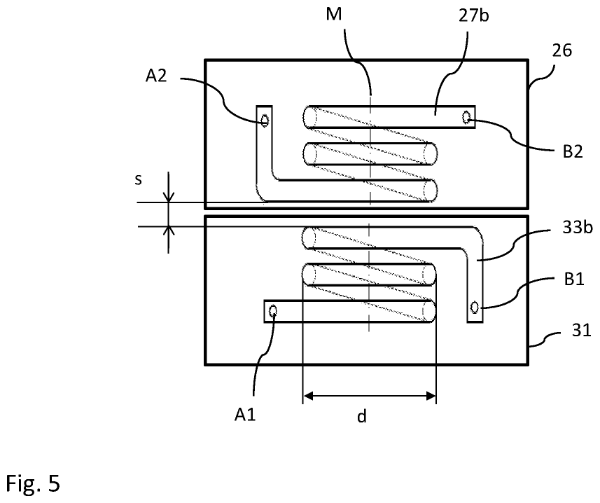

FIG. 5 shows a schematic cross section through a primary and a secondary coupling part 31, 26 of the first embodiment, the primary inductor and the secondary inductor being formed as cylindrical inductors 33b and 27b. In cylindrical inductors, the two connections of the inductor, i.e. connections A1 and B1 or A2 and B2, respectively, do not lie in one plane together with the turns of the inductor, which lie on a cylindrical jacket, for example. As shown in FIG. 4A, the cylindrical inductors 33b and 27b can be arranged inside the particular coupling part or can abut a surface of the primary coupling part 31 or of the secondary coupling part 26. In this case, the cylindrical inductors 33b and 27b are at a distance s from one another. The two cylindrical inductors 33b and 27b have the same central axis, which is denoted by the line M in FIG. 5. The central axis can extend in any direction in the xyz coordinate system. As shown in FIG. 5, the connections A1 and B1 or A2 and B2, respectively, can be arranged on different sides of the particular cylindrical inductor or on the same side of the particular cylindrical inductor, the side being freely selectable with the exception of the side facing the other cylindrical inductor. In FIG. 5, both cylindrical inductors 33b and 27b have the same connection arrangement and the same dimensions. However, the two cylindrical inductors 33b and 27b can also have different connection arrangements and dimensions as well as a different number of turns. The diameter d of the inductors is an essential dimension and shown in FIG. 5. Cylindrical inductors are typically made from a tubular material having an external tube diameter of from 4 to 12 mm, the diameter d being between 30 and 200 mm. The distance s between the two cylindrical inductors is advantageously between 50% and 100% of the diameter d, i.e. between 15 and 200 mm.

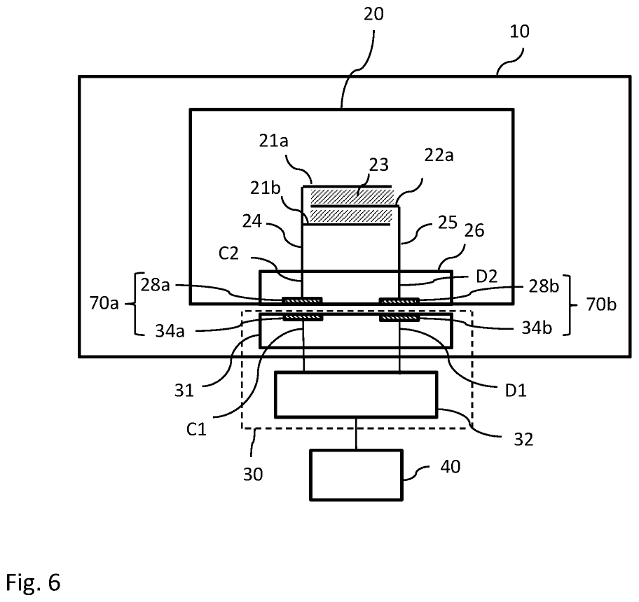

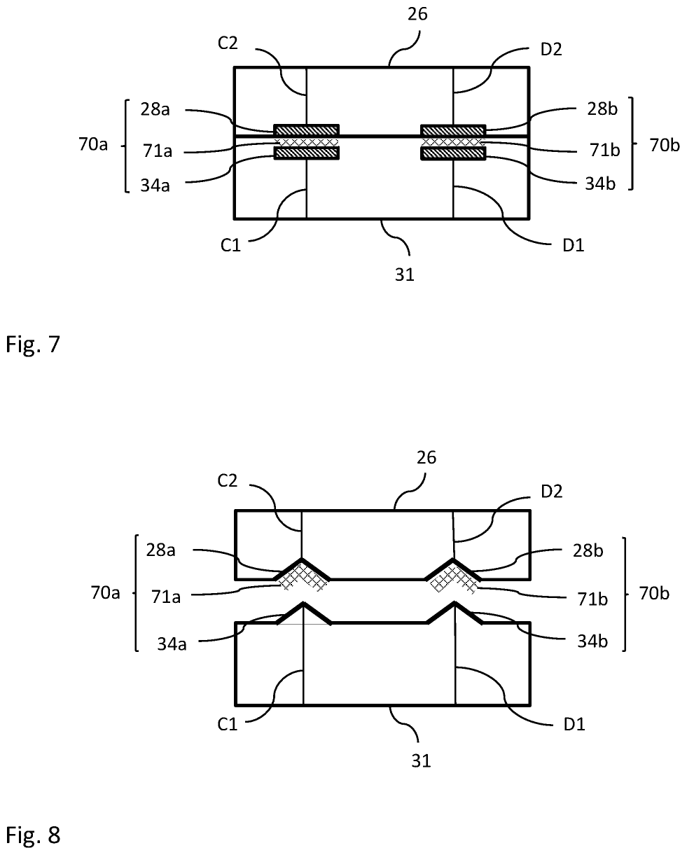

FIG. 6 is a schematic view of a second embodiment of the plasma-treatment device according to the invention, in which the coupling parts contain capacitive elements for transmitting the high-frequency power. To make the drawing clearer, only components of the plasma-treatment device essential for explaining the mode of operation have been shown. The plasma electrode unit 20 and the primary coupling part 31 of the transmission apparatus 30 are arranged in the processing chamber 10. For the sake of depicting the drawing schematically, only three plasma electrodes 21a, 21b and 22a are shown in this case, which form two pairs of plasma electrodes, between each of which a plasma 23 is generated. The primary coupling part 31 comprises a first primary electrode 34a and a second primary electrode 34b, the connections C1 and D1 of which are connected to the matchbox 32. The secondary coupling part 26 contains a first secondary electrode 28a and a second secondary electrode 28b. The connection C2 of the first secondary electrode 28a is connected to the first plasma electrodes 21a, 21b via the supply line 24, while the connection D2 of the second secondary electrode 28b is connected to the second plasma electrode 22a via the supply line 25. The first primary electrode 34a and the first secondary electrode 28a form a first coupling capacitor 70a, while the second primary electrode 34b and the second secondary electrode 28b form a second coupling capacitor 70b in the same way. An alternating electrical voltage supplied by the high-frequency generator 40 is transmitted to the plasma electrodes 21a, 21b and 22a of the plasma electrode unit 20 via the coupling capacitors 70a and 70b by means of an electromagnetic field. The primary electrodes 34a, 34b and the secondary electrodes 28a, 28b each abut a surface of the coupling part in which they are contained, said surfaces of the two coupling parts being opposite one another. A gap is formed between the primary coupling part 31 and the secondary coupling part 26 so that the atmosphere prevailing in the processing chamber 10 forms the dielectric of the particular coupling capacitor 70a, 70b. However, a dielectric made of another material can also be provided in the coupling capacitors, as is described hereinafter with reference to FIGS. 7 and 8.

FIG. 7 shows a schematic cross section through a primary and a secondary coupling part 31, 26 of the second embodiment, the primary electrodes 34a, 34b and the secondary electrodes 28a, 28b being formed as planar, i.e. flat, electrodes. In FIG. 7, a position is shown in which the alternating electrical current is transmitted. Before a step of introducing or removing the plasma electrode unit into or from the processing chamber, the primary coupling part 31 and the secondary coupling part 26 are moved away from one another so that the elements of a specific coupling capacitor that belong to different coupling parts no longer abut one another in order to reduce mechanical wear of the elements of the coupling capacitors 70a, 70b. A first dielectric 71a is arranged between the first primary electrode 34a and the first secondary electrode 28a, which dielectric forms an integral component of the first coupling capacitor 70a. In the same way, a second dielectric 71b is arranged between the second primary electrode 34b and the second secondary electrode 28b, which dielectric forms an integral component of the second coupling capacitor 70b. The dielectric 71a, 71b can be arranged on the particular primary electrode 34a, 34b or on the particular secondary electrode 28a, 28b and be rigidly connected thereto. However, it is also possible for the dielectric 71a, 71b to be formed of two separate, dielectric layers, one of which is arranged on the primary electrode 34a, 34b and the other of which is arranged on the secondary electrode 28a, 28b. The primary coupling part 31 and the secondary coupling part 26 abut one another. In this case, the electrode on which the dielectric is arranged may or may not abut the surface of the particular coupling part. FIG. 7 shows the surface of the dielectric 71a, 71b, which surface is not rigidly connected to one of the electrodes, being flush with the surface of the coupling part, i.e. lying on one plane.

The elements of the two coupling capacitors 70a, 70b, i.e. the primary electrodes 34a and 34b, the secondary electrodes 28a and 28b and the dielectrics 71a and 71b can be the same or different, at least in part, in terms of their dimensions (length, width, thickness) and the material. The dimensions and materials are determined by the capacitance to be achieved by the coupling capacitors 70a, 70b and by the dimensions and conditions (temperature, pressure, gas composition) prevailing in the plasma-treatment device.

FIG. 8 shows a schematic cross section through a primary and a secondary coupling part 31, 26 of the second embodiment, the primary electrodes 34a, 34b and the secondary electrodes 28a, 28b being formed as non-planar electrodes. FIG. 8 shows a position in which the coupling capacitors 70a, 70b are separated such that the plasma electrode unit can be inserted or removed. The electrodes 28a, 28b, 34a and 34b have a sawtooth-shaped or roof-shaped contour in cross section, individual regions of a specific electrode 28a, 28b, 34a or 34b containing planar portions. However, all the regions of a specific electrode 28a, 28b, 34a or 34b may also be curved. The secondary electrodes 28a and 28b are shaped as depressions in the surface of the secondary coupling part 26 in the case shown, while the primary electrodes 34a and 34b are formed as raised portions on the surface of the primary coupling part 31. In the present case, the dielectrics 71a, 71b are arranged on the particular secondary electrode 28a or 28b and have the same contour as the electrodes 28a, 28b, 34a and 34b. The electrodes 28a, 28b, 34a and 34b and the dielectrics 71a, 71b are shaped in this case so as to engage in one another when the coupling capacitors 70a, 70b are closed, without the formation of a parasitic gap. Furthermore, they are advantageously shaped so as to cause the primary electrodes 34a, 34b to self-align with respect to the respective secondary electrodes 28a, 28b when the coupling capacitors 70a, 70b are closed.

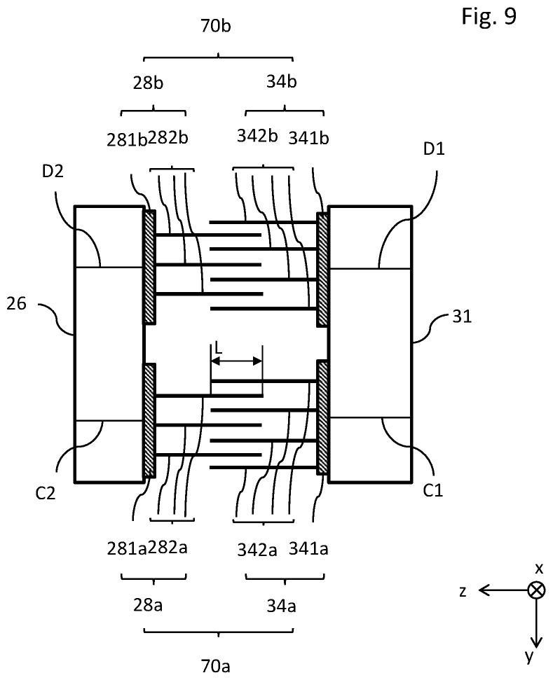

FIG. 9 shows a schematic cross section through a primary and a secondary coupling part 31, 26 of the second embodiment, in which the electrodes 28a, 28b, 34a and 34b of the coupling capacitors 70a, 70b are formed as comb electrodes. In order to make the drawing clearer, the secondary coupling part 26 has been shown to be displaced further in the positive z direction than is the case in real life. The electrodes 28a, 28b, 34a and 34b each consist of a connecting region 281a, 281b, 341a and 341b and one or more plate-shaped regions 282a, 282b, 342a and 342b. In this case, the plate-shaped regions 282a, 282b, 342a and 342b extend from the particular connecting region 281a, 281b, 341a and 341b in the z direction and in the x direction and are spaced apart from one another in the y direction. The directions of the xyz coordinate system correspond to the directions shown with reference to FIGS. 1 and 2. This means: the view in FIG. 9 is a view of the two coupling parts 26 and 31 in the direction of movement of the plasma electrode unit. The plate-shaped regions 282a, 282b, 342a and 342b are therefore formed such that the plasma electrode unit together with the plate-shaped regions 282a and 282b contained in the secondary coupling part 26 can be inserted into and removed from the intermediate spaces between the plate-shaped regions 342a and 342b of the stationary primary coupling part 31, without the plate-shaped regions 282a, 282b, 342a and 342b of the two coupling parts 26, 31 touching. In this case, when the plasma electrode unit is inserted, equal distances in the range of 0.1 and 10 mm, measured in the y direction, are formed between the plate shaped regions 282a and 342a or 282b and 342b, respectively. In this case, the plate-shaped regions overlap in the z direction over a region having an overlapping height L, which, as already mentioned, is larger in real life than in the view in FIG. 9 and preferably corresponds to the length of the plate-shaped regions 282a, 282b, 342a and 342b in the z direction, minus a value between 0.1 and 10 mm. The capacitance achieved in the coupling capacitors 70a, 70b is determined by the overlapping height L in the z direction and an overlapping length in the x direction and by the distance between the individual plate-shaped regions 282a and 342a or 282b and 342b in the y direction. This design is advantageous in that the requirements in respect of accurately positioning the plasma electrode unit in the x direction are relatively low. For example, if the plate-shaped regions 282a, 282b, 342a and 342b were to have a length of 180 mm in the x direction, a positioning accuracy of the plate-shaped regions 282a, 282b, 342a and 342b of ±5 mm in the x direction is sufficient. Furthermore, even continuous systems can be implemented, in which the plasma electrode unit is continuously moved, even during the treatment process; the plate-shaped regions 342a and 342b of the primary electrodes 34a, 34b extending in the x direction over the entire length of the processing chamber in this case (with the exception of edge regions, which are required for insulating the primary electrodes 34a, 34b from the walls of the processing chamber). Preferably, the plasma electrode unit moves linearly along the x direction.

The precise design of the primary coupling part and of the secondary coupling part in all the embodiments can be optimally adapted to the conditions in the processing chamber and to the electrical power required for generating and maintaining the plasma between the plasma electrodes of a pair of plasma electrodes. In this case, different embodiments and designs may optionally also be combined.

### LIST OF REFERENCE NUMERALS

1, la plasma-treatment device
10 processing chamber
11, 12 lock
20, 20a-c plasma electrode unit
21a-c first plasma electrode of a pair of plasma electrodes
22a-c second plasma electrode of a pair of plasma electrodes
23 plasma
24, 25 supply line
26, 26a-c secondary coupling part
27 secondary inductor
27a secondary inductor in the form of a flat inductor
27b secondary inductor in the form of a cylindrical inductor
28a first secondary electrode
28b second secondary electrode
281a, b connecting region of a secondary electrode
282a, b plate-shaped region of a secondary electrode
30, 30a-c transmission apparatus
31, 31a-c primary coupling part
32, 32a-c matchbox
33 primary inductor
33a primary inductor in the form of a flat inductor
33b primary inductor in the form of a cylindrical inductor
34a first primary electrode
34b second primary electrode
341a, b connecting region of a primary electrode
342a, b plate-shaped region of a primary electrode
40, 40a-c generator
50 adjustment unit
60 alignment device
70a first coupling capacitor
70b second coupling capacitor
71a first dielectric
71b second dielectric
A1, B1 connections of the primary inductor
A2, B2 connections of the secondary inductor
C1, D1 connections of the primary electrodes
C2, D2 connections of the secondary electrodes
a₁, a₂ edge length of the primary and secondary inductor
b width of the primary and secondary inductor
d diameter of the primary and secondary inductor
h height of the flat inductor
distance between the inductive or capacitive elements of the primary
coupling part and of the secondary coupling part
L overlapping height of the plate-shaped regions

1. Plasma-treatment device, comprising
a processing chamber,
a plasma electrode unit, which consists of at least one pair of plasma electrodes made up of two parallel plasma electrodes that are opposite one another and are electrically insulated from one another, said plasma electrode unit being suitable for insertion into and removal from the processing chamber, and
a transmission apparatus, at least part of which is arranged in the processing chamber and which is suitable for transmitting electrical power, which is required for generating and maintaining a plasma between the plasma electrodes of a pair of plasma electrodes of the plasma electrode unit, from a generator arranged outside the processing chamber and to the plasma electrode unit when the plasma electrode unit is in a treatment position in the processing chamber,
characterised in that
the transmission apparatus contains a primary coupling part arranged inside the processing chamber,
the plasma electrode unit contains a secondary coupling part, which is rigidly connected to the plasma electrode unit, and
the primary coupling part and the secondary coupling part are arranged so as to be suitable for transmitting high-frequency electrical power supplied by the generator to the plasma electrode unit by means of one or more electromagnetic fields and without an electrical ohmic contact.

2. Plasma-treatment device according to claim 1, characterised in that the high-frequency electrical power transmitted has a frequency in the range from 10 kHz to 100 MHz.

3. Plasma-treatment device according to claim 1, characterised in that
the plasma electrodes of the plasma electrode unit are designed so as to be arranged in the plasma-treatment device in a manner insulated against earth potential when the plasma electrode unit is in a treatment position, and
the primary coupling part and the secondary coupling part are suitable for symmetrically supplying the high-frequency power to plasma electrodes of the plasma electrode unit that are assigned to one another with respect to earth potential.

4. Plasma-treatment device according claim 1, characterised in that the plasma-treatment device further comprises an adjustment unit, which is suitable for moving the primary coupling part towards or away from the secondary coupling part when the plasma electrode unit is in a treatment position in the processing chamber.

5. Plasma-treatment device according to claim 1, characterised in that the primary coupling part comprises at least one primary inductor and the secondary coupling part comprises at least one secondary inductor, each secondary inductor being assigned to a primary inductor and one end of the secondary inductor being connected to a plasma electrode of a pair of plasma electrodes so as to conduct electricity and the other end of the secondary inductor being connected to the other plasma electrode of said pair of plasma electrodes so as to conduct electricity in each case, the at least one primary inductor being suitable for generating an electromagnetic field by means of the high-frequency power supplied by the generator, and the at least one secondary inductor being suitable for absorbing the electromagnetic field generated by the at least one primary inductor.

6. Plasma-treatment device according to claim 5, characterised in that at least one of the at least one primary inductor and at least one of the at least one secondary inductor assigned to said primary inductor are formed as flat inductors.

7. Plasma-treatment device according to claim 5, characterised in that at least one of the at least one primary inductor and at least one of the at least one secondary inductor assigned to said primary inductor are formed as cylindrical inductors.

8. Plasma-treatment device according to claim 5, characterised in that at least the secondary inductor is made of a material having a temperature resistance to at least 450° C. and a degree of electrical conductivity of at least 10+7 S/m under vacuum conditions.

9. Plasma-treatment device according to claim 1, characterised in that the primary coupling part comprises at least two primary electrodes and the secondary coupling part comprises at least two secondary electrodes, each secondary electrode being assigned to a specific primary electrode and being suitable for forming a capacitor together therewith, and the primary electrode of a first capacitor being connected to one connection of the generator so as to conduct electricity and the primary electrode of a second capacitor being connected to the other connection of the generator so as to conduct electricity, and the secondary electrode of the first capacitor being connected to one plasma electrode of a pair of plasma electrodes so as to conduct electricity and the secondary electrode of the second capacitor being connected to the other plasma electrode of said pair of plasma electrodes so as to conduct electricity.

10. Plasma-treatment device according to claim 4, characterised in that at least one of the primary electrode or the secondary electrode of a specific capacitor comprises a dielectric, which is in mechanical contact with the respectively assigned secondary electrode or primary electrode of the specific capacitor when the plasma electrode unit is in a treatment position in the processing chamber and the adjustment unit has moved the primary coupling part towards the secondary coupling part.

11. Plasma-treatment device according to claim 9, characterised in that the primary electrode and the secondary electrode of at least one specific capacitor each have a non-planar surface, which is opposite the other electrode in each case and corresponds to the shape of the non-planar surface of the other electrode in each case.

12. Plasma-treatment device according to claim 9, characterised in that the primary electrode and the secondary electrode of at least one specific capacitor each comprise at least two plate-shaped regions, which each extend from a common connecting region towards the respective other electrode and in a direction in which the plasma electrode unit is inserted into and removed from the processing chamber, the plate-shaped regions of the primary electrode and of the secondary electrode being opposite one another, at least in part, when the plasma electrode unit is in a treatment position in the processing chamber.

13. Plasma-treatment device according to claim 1, characterised in that the plasma-treatment device contains a plurality of plasma electrode units and a plurality of transmission apparatuses, each plasma electrode unit being assigned to a specific transmission apparatus and each transmission apparatus comprising a primary coupling part and each plasma electrode unit comprising a secondary coupling part, which are suitable for transmitting high-frequency power to the particular plasma electrode unit by means of electromagnetic fields and without being in electrical ohmic contact with one another.

14. Method for operating a plasma-treatment device according to claim 1, comprising the steps of:
inserting the plasma electrode unit into the processing chamber along a first direction until the plasma electrode unit is in a treatment position in the processing chamber and the primary coupling part and the secondary coupling part are opposite one another at least in part,
generating an electromagnetic field in the primary coupling part by applying high-frequency power supplied by a generator and transmitting the high-frequency power to the secondary coupling part after the step of inserting the plasma electrode unit has finished, thus generating and maintaining a plasma between the plasma electrodes of a pair of plasma electrodes of the plasma electrode unit,
disconnecting the primary coupling part from the high-frequency power supplied by the generator after an operating aim has been reached in the processing chamber,
removing the plasma electrode unit from the processing chamber along the first direction after the primary coupling part has been disconnected from the high-frequency power supplied by the generator.

15. Method according to claim 14, characterised in that
when the plasma electrode unit is inserted, it is moved such that, once it reaches the treatment position, a first distance is provided between the primary coupling part and the secondary coupling part,
after the plasma electrode unit has been inserted into the processing chamber and before the electromagnetic field has been generated, the primary coupling part is moved towards the secondary coupling part by means of an adjustment unit until a second distance is formed between the primary coupling part and the secondary coupling part, the second distance being smaller than the first distance, and
after the primary coupling part has been disconnected from the high-frequency power and before removing the plasma electrode unit from the processing chamber, the primary coupling part is moved away from the secondary coupling part by means of the adjustment unit until a third distance is formed between the primary coupling part and the secondary coupling part, the third distance being greater than the second distance.

16. Method according to claim 14, characterised in that
the primary coupling part comprises at least one primary inductor and the secondary coupling part comprises at least one secondary inductor, and
at least the primary inductor is cooled during the step of generating an electromagnetic field.
